(19) United States
(12) Patent Application Publication
(10) Pub. No.: US 2025/0062659 A1
(43) Pub. Date: Feb. 20, 2025

(54) SYSTEM AND METHOD FOR CONVERTING WASTE HEAT INTO ELECTRICITY

(71) Applicant: NovoPower International Inc., Montréal (CA)

(72) Inventors: Philip RAPHALS, Montréal (CA); Tamas BERTENYI, Montréal (CA); Joris NAUDIN, Montreal (CA)

(21) Appl. No.: 18/705,638

(22) PCT Filed: Oct. 31, 2022
(86) PCT No.: PCT/IB2022/060466

§ 371 Date: Apr. 29, 2024

(30) Foreign Application Priority Data
Oct. 29, 2021 (CA) 3136893

(51) Int. Cl. H02K 7/18; F03G 7/06

(52) U.S. Cl. CPC H02K 7/1884; F03G 7/0641

(57) ABSTRACT

The present invention provides a waste-heat recovery and power generation system for liquid-cooled data centres and computing centres, to capture and use their waste heat and use it to produce electricity, allowing the data centres and computing centres to self-supply a part of their electrical needs in a cost-effective manner. The system uses heat collected from the electronic components to heat and vaporize a working fluid; uses the vaporized working fluid(s) to power an expander; uses the expander to drive an electric generator; uses a condenser to condense the partially cooled vapour expelled from the expander; uses a pump to return the condensed working fluid to the evaporator system; and uses a control system to manage the valves of the heat-capture system and the expander, and to manage the generation system order to maximize efficiency and power quality.

### FIELD OF THE INVENTION

The present invention pertains to the field of waste heat recovery and reutilisation, and in particular to the production of electrical power from waste heat recovered from assemblages of computing equipment, as typically found in data centres, computing centres, server farms and similar installations (referred to collectively herein as “data centres”).

In particular, though not exclusively, the present invention relates to a system for converting waste heat from at least one assemblage of computing equipment into electricity, wherein the system further includes an integrated expander-generator assembly and a brake assembly. Moreover, the present invention relates to a method for converting waste heat from at least one assemblage of computing equipment into electricity.

### BACKGROUND

In recent years, use of high-power computing equipment has increased tremendously. Computing equipment is used in data centres for various applications such as internet services, e-commerce transactions, data storage, data management, cryptocurrency mining, and the like. A vast amount of electricity is required to power such data centres. The electricity used by the computing equipment results in production of waste heat, which must be removed in order to maintain the temperatures of electronic components of the computing equipment within their manufacturers' specifications. Considerable amounts of electrical energy are expended in order to remove this waste heat, which results in costs for an operator of the data centre and in greenhouse gas emissions and other environmental impacts associated with the production of this electricity.

In an attempt to mitigate aforesaid problems, several approaches have been used to manage and re-use the heat emanating from the computing equipment. Various system and methods have been used to capture and utilize the waste heat. For example, the heat emanating from the data centres has been utilized to heat greenhouses and to provide heat to district heating systems.

Such approaches increase the sustainability of data centre operations. However, there are several limitations associated with conventional systems and methods for recovering and reusing waste heat of data centre operations. If the waste heat could be converted to electricity, it could be used for a wide variety of purposes, including supplying electrical power to the assemblages of computing equipment that produce the waste heat. Self-supply of electricity from a data centre's own waste heat would constitute an example of a circular economy, and would contribute to the data centre's sustainability.

Traditionally, air cooling has been utilized to dispose of such waste heat in data centres. However, air cooling requires considerable amounts of energy, and the heat that can be recovered from heated air is of limited usefulness.

The drive to reduce the amount of energy required to cool data centres' computing equipment and thereby to reduce both the cost of operating these centres and their environmental impacts has led to considerable innovation, especially with regard to the use of liquids to cool the computing equipment (“liquid cooling”). As it is more efficient to extract heat from a liquid than from air, liquid cooling reduces the cost of cooling the electronic components of computing equipment.

One innovative type of liquid cooling technology is known as “immersion cooling”, where the electronic components are immersed in a bath of dielectric fluid.

A second innovation consists of phase-change (or “two-phase”) immersion cooling. Here, the dielectric fluid in which heat-generating electronic components are immersed is a phase-change fluid that evaporates when heated. The vapor rises in a chamber containing the electronic components, and is condensed by a series of coils above them through which a cooling agent circulates. The dielectric fluid condenses on the coils, and then falls back into a bath containing the electronic components. Through the present innovation, the cost of cooling is still further reduced.

Other forms of liquid cooling have also been developed, including direct-to-chip and other configurations, which allow much of the heat given off by computing equipment to be removed by using a liquid heat transfer medium.

Liquid cooling facilitates the use of data centre waste heat for heating buildings or greenhouses, or for other thermal purposes. However, the infrastructure configurations required to use waste heat for these purposes greatly limits their application. Furthermore, these approaches do not actually recycle the recovered heat to reduce the power required by the data centre. A “circular economy” innovation that would convert some of this waste heat to electric power would result in allowing the facility operator to produce some of the electricity required to power its computing equipment from its own waste heat, thereby reducing its costs and its environmental footprint. Therefore, there is a need for waste heat generation systems that are adapted to data centres.

Because, in liquid-cooled data centres, the waste heat is collected in liquid form at relatively higher temperatures, it is more feasible to produce electricity from this waste heat than would be the case in air-cooled data centres. Thus, the gradual shift toward liquid cooling in data centres opens the door to using waste heat to reduce data centres' power requirements.

A number of Organic Rankine Cycle (hereinafter, “ORC”) solutions have been proposed to produce power from waste heat. These ORC solutions use the waste heat to evaporate an fluid (usually, an organic fluid) to form a corresponding vapour, and use the vapour to drive a power conversion device such as a turbine or screw expander. However, conventional ORC systems generally require temperatures higher than those to be found in captured waste heat from a data centre, including those using liquid cooling. Conventional ORC systems are thus unable to economically convert the waste heat of a data centre into power. Furthermore, the amount of waste heat available can vary greatly over time, and the turbines and screw expanders used in conventional ORC systems are generally efficient over only a narrow range of operating conditions.

For all these reasons, there is a need for an innovative system to allow operators of data centres and other assemblies of computing equipment to capture their waste heat and reuse (namely “recycle”) it to produce electricity in a cost-effective manner. The purpose of the present invention is to make possible such recycling of data centre waste heat.

The preceding background information is provided to reveal information believed by the Applicant to be of possible relevance to the present invention. No admission is necessarily intended, nor should be construed, that any of the preceding information constitutes prior art against the present invention.

### SUMMARY OF THE INVENTION

An object of the present invention is to provide a waste-heat recovery and power generation system for computing centres, data centres, server farms, cryptocurrency miners and other assemblages of computing equipment.

According to a first aspect, there is provided a system for converting waste heat from at least one assemblage of computing equipment into electricity, the system comprising:
a heat capture subsystem configured to hold a liquid heat transfer medium therein, wherein the heat capture subsystem, in use, enables the liquid heat transfer medium to absorb the waste heat from the at least one assemblage of computing equipment;
an evaporator subsystem, comprising a phase-change working fluid, wherein the working fluid is configured to change from a liquid state to a gaseous state by absorbing the waste heat absorbed into the liquid heat transfer medium;
a modular expander subsystem comprising at least one modular expansion device, wherein the expander subsystem is coupled to the evaporator subsystem via at least one fluid flow control element, wherein pressurized working fluid in the gaseous state is directed towards the expander subsystem using the at least one fluid flow control element, and wherein the pressurized gaseous working fluid expands, producing mechanical work;
a modular generation subsystem coupled to the expander subsystem, wherein a modular generator, in operation, is configured to produce electrical energy from the mechanical work created by the expansion of the pressurized gaseous working fluid in the modular expansion device;
a condenser subsystem connected to the expander subsystem, wherein a condenser, in operation, liquifies expanded working fluid from a gaseous state or a mixed state to the liquid state, and then returns working fluid in the liquid state to the evaporator subsystem; and
a control subsystem.

According to a second aspect, there is provided an integrated expander-generator assembly comprising:
a plurality of permanent magnets;
a plurality of coils;
a piston; and
a cylinder,
arranged such that the plurality of permanent magnets are arranged inside the piston and the plurality of coils are arranged along a length of the cylinder,
and wherein, in use, pressurized gas expanding in the integrated expander-generator assembly produces a mechanical force that actuates the piston in the cylinder, and wherein upon such actuation, a relative motion between the plurality of permanent magnets and the plurality of coils produces electricity.

Optionally, the integrated expander-generator assembly is used in the system of the first aspect.

According to a third aspect, there is provided a brake assembly comprising at least one resistor and at least one relay, wherein, when a fault condition is detected, the at least one relay is configured to electrically couple a generator with the at least one resistor to cause deceleration of a shaft of the generator to hinder movement of the shaft of the generator.

Optionally, the brake assembly is used in the system of the first aspect.

According to a fourth aspect, there is provided a method for converting waste heat from at least one assemblage of computing equipment into electricity, the method comprising:
arranging a heat capture subsystem to hold a heat transfer fluid therein, wherein the heat capture subsystem, in use, enables the heat transfer fluid to absorb the waste heat from the at least one assemblage of computing equipment;
arranging an evaporation subsystem comprising a phase change heat exchanger to be coupled to the heat capture subsystem, and filling the phase change heat exchanger with a working fluid, wherein the working fluid is vaporized from a liquid phase to a gaseous phase when the working fluid absorbs the waste heat from the heat transfer fluid, the working fluid being selected based upon the temperature of the waste heat released by the at least one assemblage of computing equipment;
arranging an expander subsystem to be coupled to the evaporator subsystem via at least one fluid flow control element, wherein pressurized vapour of the working fluid that emanates from the pressure-resistant vessel is directed towards the expander subsystem using the at least one fluid flow control element, and wherein when the expander subsystem is in use, the pressurized working fluid vapour is allowed to expand in the expander subsystem, producing a mechanical force for actuating the expander;
arranging a generator subsystem to be coupled to the expander subsystem, wherein the generator, when in operation, produces the electricity using the mechanical force created by the expansion of the pressurized working fluid vapour;
arranging a condenser subsystem to be connected to the expander subsystem, wherein the condenser, when in operation, liquifies expanded vapour of the working fluid from the gaseous phase to the liquid phase, and wherein the condensed working fluid is returned under pressure to the evaporator subsystem; and
configuring a control subsystem for controlling operations of other subsystems.

According to a fifth aspect, there is provided a system to recover and utilise waste heat from a computing centre, data centre or other assemblage of computing equipment including electronic components, in which:
heat from the operation of the electronic components is absorbed by a liquid;
heat from said liquid is transferred, directly or indirectly, to a working fluid in a pressure-resistant vessel, vaporizing said working fluid;
ports or valves operated by a control system allow vaporized working fluid to pass from the pressure-resistant vessel to an expander;
vaporized working fluid released from the pressure-resistance vessel is allowed to expand in an expander, producing mechanical power;
the mechanical power produced in the expander is used to power a generator, producing electricity;
a condenser is used to condense the partially cooled vapour expelled from the expander;
a pump returns the condensed working fluid to the pressure-resistant vessel; and
a control system controls the operations of said valves and pumps.

According to a sixth aspect, there is provided a method for recovering and utilising waste heat from a computing centre, data centre or other assemblage of computing equipment including electronic components, the method comprising:
collecting the heat from the electronic components in a phase-change dielectric fluid in which they are immersed, contained in a pressure-resistance vessel;
restricting egress of the vaporized working fluid from the pressure-resistant vessel such that the electronic components remain immersed in liquid dielectric fluid, and the pressure in the vessel increases to a selected level;
directing vaporized working fluid(s) released from the pressure-resistant vessel to an expander, where they produce mechanical power;
using the mechanical power produced in the expander to power a generator, producing electricity.

### BRIEF DESCRIPTION OF THE DIAGRAMS

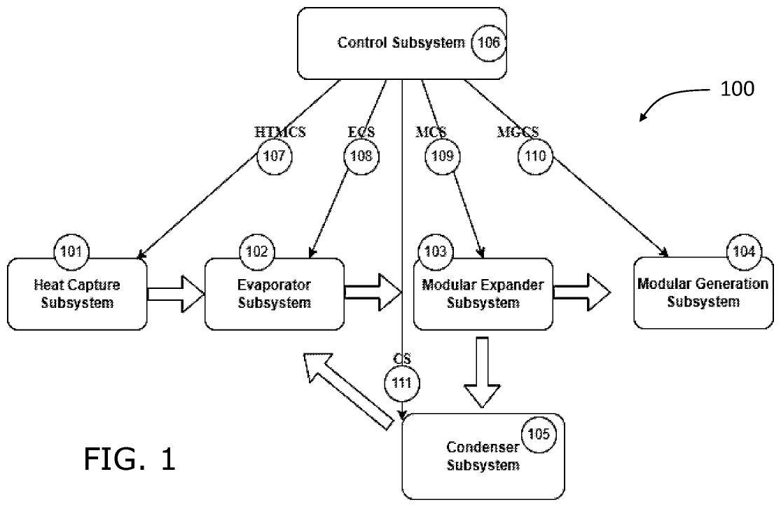

FIG. 1 is a schematic illustration of an overall architecture of a system for converting waste heat into electricity according to the present disclosure, wherein the system includes a Heat Capture Subsystem, an Evaporator Subsystem, a Modular Expander Subsystem, a Modular Generator Subsystem, and a Condenser Subsystem, as well as a control subsystem that controls each of the other subsystems.

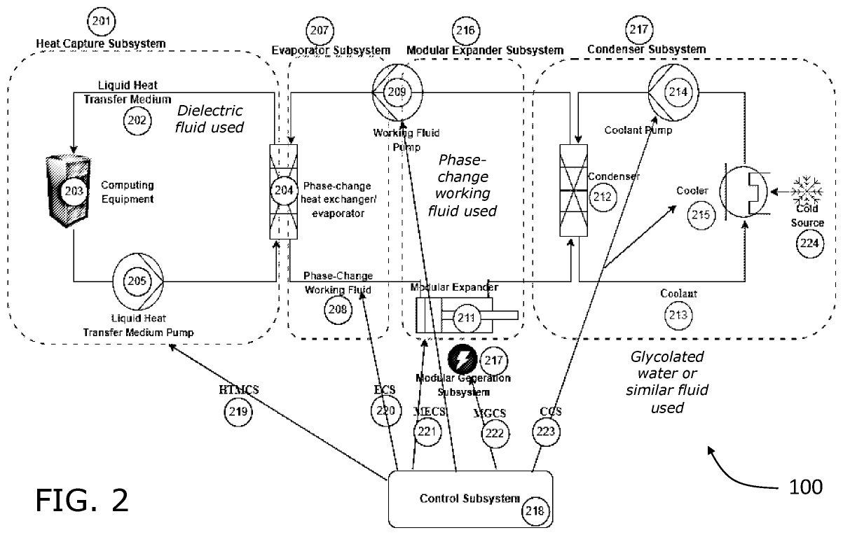

FIG. 2 is a schematic illustration of a more detailed view of the system of FIG. 1, wherein many key components of each Subsystem, as well as their elements are controlled by the Control Subsystem.

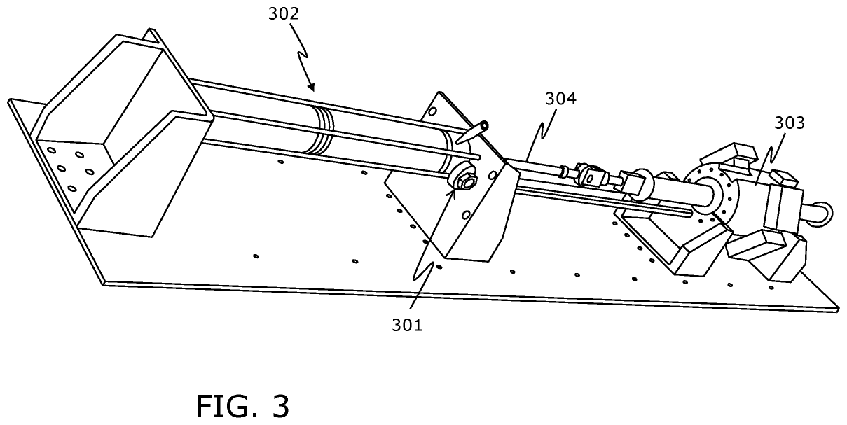

FIG. 3 is an illustration of an embodiment of a linkage that is useable between the Modular Expander Subsystem and the Modular Generator Subsystem.

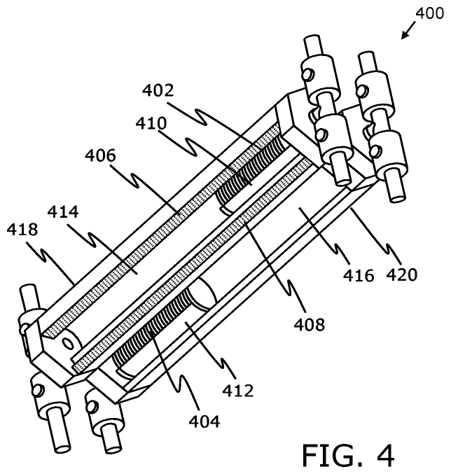

FIG. 4 is an illustration of an embodiment of an integrated expander-generator assembly.

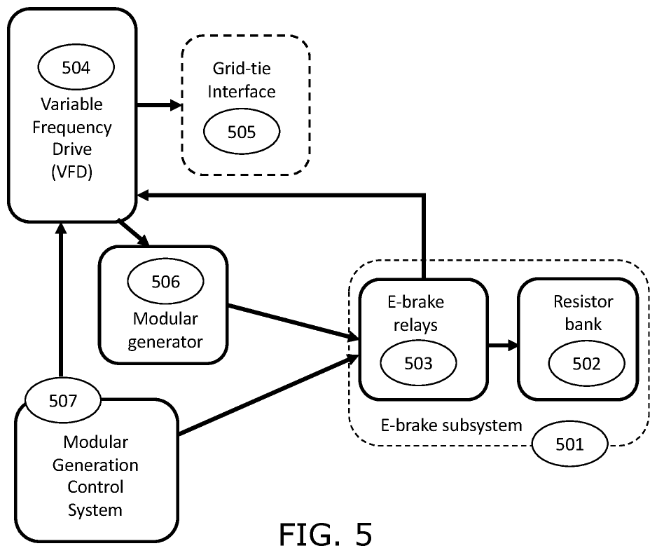

FIG. 5 is an illustration of an architecture of an electronic emergency brake.

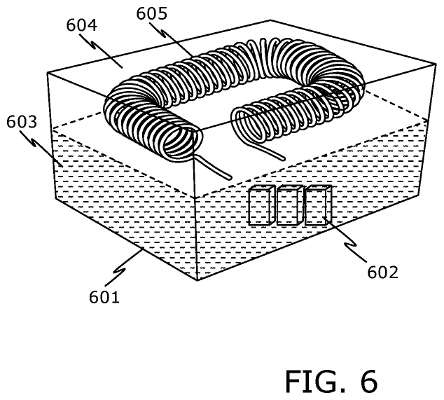

FIG. 6 is a schematic illustration of an embodiment of the Heat Capture Subsystem and the Expander Subsystem for use in a two-phase immersion cooling system.

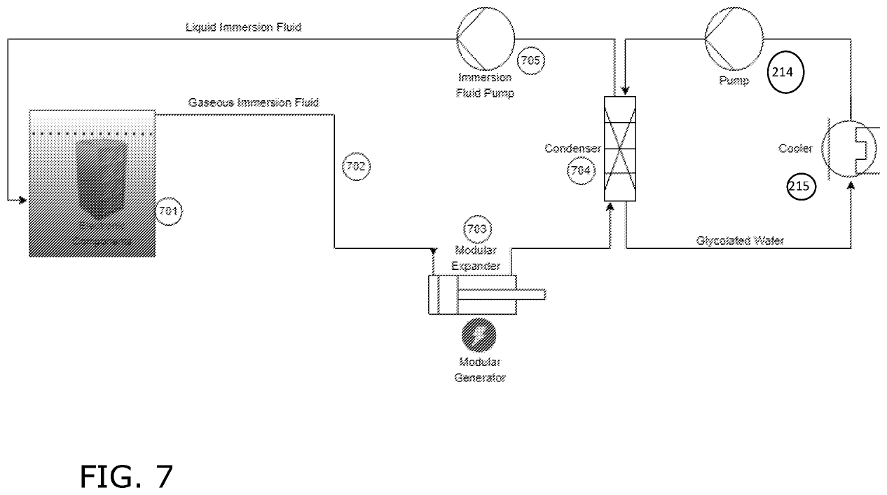

FIG. 7 is a schematic illustration of an embodiment for a two-phase immersion cooling system in which a dielectric fluid also plays a role of a phase-change working fluid.

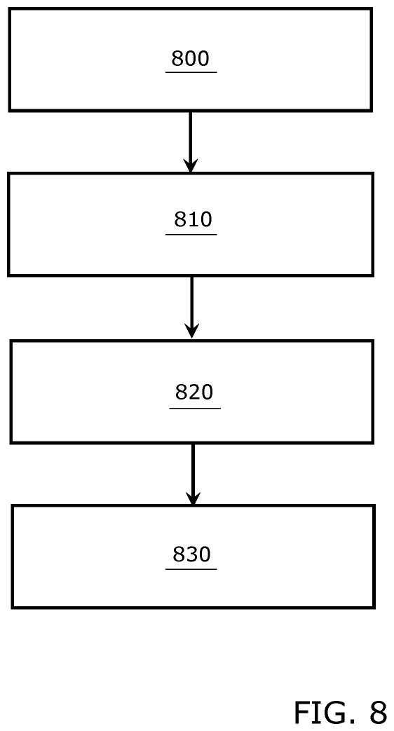

FIG. 8 is a flow chart depicting steps of a method of the present disclosure.

### DETAILED DESCRIPTION OF THE INVENTION

The following detailed description illustrates embodiments of the present application and ways in which they can be implemented. Although some modes of carrying out the present teachings have been disclosed, those skilled in the art would recognize that other embodiments for carrying out or practising the present teachings are also possible.

As used herein, the term “about” refers to a +/−10% variation from the nominal value. It is to be understood that such a variation is always included in a given value provided herein, whether or not it is specifically referred to.

As used herein, the term “data centre” refers to any computing centre, data centre, server farm, cryptocurrency installation or any other large assemblage of computers or related electronics.

As used herein, the term “dielectric fluid” refers to any fluid that displays extremely low conductivity of electricity, namely effectively an electrical insulator for practical purposes.

Unless defined otherwise, all technical and scientific terms used herein have the same meaning as commonly understood by one of ordinary skill in the art to which this invention belongs.

### Overview

The present invention provides a waste-heat recovery and power generation system 100 (hereinafter, sometimes referred to as “system 100”) as illustrated in FIG. 1 that is configured to efficiently and cost effectively capture waste heat from data centres, and to convert some of that captured waste heat to electricity.

While some of its component elements of the system 100 have been described before in known art, they have not been configured in a way pursuant to the present disclosure. The system 100 is configured to allow data centres to economically produce electricity from their waste heat, and to thereby self-supply a portion of their operating power requirements, in order to operate in a more sustainable manner as part of a circular economy. In the invention of the present disclosure, diverse elements are combined and integrated in an innovative way, thereby overcoming the obstacles faced by other systems.

The system 100 for data centres is configured to: a) capture waste heat from electronic components of the data centres; and b) convert some of that captured waste heat to electricity.

According to one or more embodiments, the system 100 illustrated in FIG. 1 comprises:
a Heat Capture Subsystem 101;
an Evaporator Subsystem 102;
a Modular Expander Subsystem 103;
a Modular Generation Subsystem 104;
a Condenser Subsystem 105; and
a Control Subsystem 106, which controls aspects of the other aforesaid Subsystems.

These Subsystems 101, 102, 103, 104, 105, 106 are connected together as illustrated to enable the system 100 to function to efficiently and cost effectively capture waste heat from data centres, and to convert some of that captured waste heat to electricity.

In some embodiments, each of these Subsystems 101, 102, 103, 104, 105, 106 use controllers that may allow the operating parameters of the system 100 to be varied in real time.

Hereinbelow, functionalities of each of the Subsystems 101, 102, 103, 104, 105, 106 as described in the preceding paragraphs are explained without any limitations. It may be appreciated by a person skilled in the art that various alternatives may be implemented for achieving the described functionalities without departing from the spirit and the scope of the present disclosure.

### Detailed Description of the Subsystems 101, 102, 103, 104, 105, 106

In FIG. 2, there is shown a more detailed view of the system 100.

### Heat Capture Subsystem 201

The system 100 includes a Heat Capture Subsystem 201 that comprises:
a liquid heat transfer medium 202 which cools computing equipment including electronic components 203 by extracting heat from the electronic components 203,
optionally, in some embodiments, a bath of dielectric fluid (not shown), in which the electronic components 203 are immersed;
optionally, in some embodiments, a hermetically sealed bath of phase-change dielectric fluid (not shown), in which the electronic components 203 are immersed;
optionally, in some embodiments, a hermetically sealed and pressure-resistant vessel, within which the bath and the electronic components 203 are enclosed (not shown);
optionally, in some embodiments, an assembly of heat exchangers, pipes and manifolds that brings the liquid heat transfer medium 202 in proximity to the heat-producing electronic components 203, without contacting them (not shown);
optionally, in some embodiments, a phase-change heat exchanger 204 to extract heat from the dielectric fluid;
optionally, in some embodiments, a liquid heat transfer medium pump 205 to circulate the liquid heat transfer medium 202, and a heat transfer medium control system (HTMCS) 219, to control the operation of aforesaid pump 205.

More specifically, the Heat Capture Subsystem 201 comprises the liquid heat transfer medium 202 which cools the electronic components 203 of the computing equipment, by extracting heat from the electronic components 203, and the liquid heat transfer medium pump 205 to circulate the liquid heat transfer medium 202. Operation of the pump 205 is controlled by the heat transfer medium control subsystem 219.

In some embodiments, the liquid heat transfer medium 202 is contained within an assemblage of pipes and manifolds and is circulated directly to the heat-producing electronic components 203 (“direct-to-chip cooling”) (not shown).

In some embodiments, the liquid heat transfer medium 202 includes a bath of dielectric fluid (“single-phase immersion cooling”, not shown), in which the electronic components 203 of the computing equipment are immersed. The dielectric fluid is then circulated, by using the liquid heat transfer medium pump 205, to the Evaporator Subsystem 207 (102). In the phase-change heat exchange evaporator 204, the dielectric fluid transfers heat to a phase-change working fluid 208 and is thereby cooled before being returned to the bath. In other embodiments, the phase-change heat exchange evaporator 204 may optionally include a heat exchanger in the form of tubes located in the liquid heat transfer medium 202 (not shown).

In FIG. 2, there is also included the Control Subsystem 106 (218).

In FIG. 6, in some embodiments, the electronic components 203 (602) and the bath of dielectric fluid 603 are contained within a hermetically sealed vessel 601; the dielectric fluid 603 is partially vaporized by the heat from the electronic components 602; such a manner of cooling is referred to as being “two-phase immersion cooling”. In some embodiments, the vapour of the dielectric fluid 603 is generated from metal or ceramic heatsinks to which the electronic components 602 are thermally coupled. In some embodiments, the vapour remains in the vessel 601, where it is condensed by cooling coils 605 suspended above the electronic components 602 (203) through which a heat-transfer agent is circulated, wherein the condensed vapour of the dielectric fluid falls back into the bath in liquid form (603). In other embodiments, the phase-change working fluid may be introduced directly into the coils 605, thereby allowing vaporization of the phase-change working fluid to occur within the cooling coils in the hermetically sealed vessel 601, while at the same time cooling and liquefying the gaseous dielectric fluid. It is understood that the form of the coils 605 shown in FIG. 6 is purely illustrative, and that they may take any other form. In these embodiments, the coils 605 constitute the Evaporator Subsystem 102, wherein the Evaporator Subsystem 102 is configured in use to vaporize the phase-change working fluid.

In some embodiments, the hermetically sealed vessel 601 is also pressure-resistant, for example as illustrated by 701 in FIG. 7. In these embodiments, the dielectric fluid contained in the pressure-resistant vessel 701 is partially vaporized by the heat from the electronic components 203, 602. Resulting pressurized vapour 702 is then released to a Modular Expander Subsystem 103, 703 through a port or a valve controlled by the Control Subsystem 106 (not shown in FIG. 7), allowing the liquid heat transfer medium 202 to also act as the phase-change working fluid, thereby allowing the Heat Capture Subsystem 101, 201 to also carry out the functions of the Evaporator Subsystem 102, 207. The expanded gaseous dielectric fluid is then condensed in a condenser 704, and is then pressurized and returned to the pressure-resistant vessel 701 by the immersion fluid pump 205, 705.

In some embodiments, the liquid heat transfer medium 202 is further heated by means of a solar thermal collector (not shown), or by any other means, to further increase its temperature.

In some embodiments, the Heat Capture Subsystem 101, 201 includes one or more valves (not shown) to bypass the Evaporator Subsystem 102, 207 and to introduce the heated liquid heat transfer medium 202 to a heat exchanger (not shown) that is directly connected to a cooler, in order to continue operations whenever the Evaporator Subsystem 102, the Modular Expander Subsystem 103 or the Modular Generation Subsystem 104 is unavailable due to maintenance or other reasons.

### Evaporator Subsystem 102, 207

Referring again to FIG. 2, in some embodiments, the Evaporator Subsystem 102, 207 includes:
a phase-change working fluid 208 chosen according to its thermodynamic and other properties;
the phase-change heat exchanger 204 as aforementioned that transfers the heat contained in the liquid heat transfer medium 202 to said phase-change heat exchanger 204; and
the working fluid pump 205 that circulates the working fluid between the phase-change heat exchanger 204, a modular expander 211 and a condenser 212. The working fluid 208, once evaporated in the phase-change heat exchange evaporator 204, is then released to the Modular Expander Subsystem 103, 211 through a port or a valve (not shown) controlled by the Modular Expander Control Subsystem 106, 221.

In one or more embodiments, the working fluid 208 consists of or comprises a chemical substance or a combination of chemical substances selected based on their physical properties that optimize the thermodynamic efficiency of the system 100, taking into account the temperatures of the liquid heat transfer medium 202 and a cold source 224 and on the following criteria:
(i) safety (non-toxic, non-inflammable);
(ii) environmentally acceptability (global warming potential, ozone layer impacts, etc.);
(iii) availability and cost; and
(iv) other criteria.

In some embodiments, a mixture of compounds may be used in order modify the thermodynamic properties of the working fluid 208 (namely, a “zeotropic” fluid). In some embodiments, the working fluid 208 may be composed of one or more compounds engineered specifically for the said purpose.

In some embodiments, the working fluid 208 consists of or comprises a substance that is a liquid at ambient temperatures and at atmospheric pressure. In other embodiments, the working fluid 208 consists of or icomprises a substance that is in a gaseous state at ambient temperatures and at atmospheric pressure. In said embodiments, the condenser is maintained at a pressure higher than atmospheric pressure, such that the working fluid 208 emerging from said condenser is in liquid form.

In one or more embodiments, where the electronic components 203 are immersed in a dielectric fluid with thermodynamic properties such that it is caused to evaporate by the heat provided by said electronic components 203 (two-phase immersion cooling), and where said bath is contained in a pressure-resistant vessel, wherein the Heat Capture Subsystem 101, 201 may also function as the Evaporator Subsystem 102, 207, as illustrated in FIGS. 6 and 7.

### Modular Expander Subsystem 103, 216

The Modular Expander Subsystem 103, 216 uses the pressurized vapour provided by the Evaporator Subsystem 102, 207 to produce mechanical work.

In one or more embodiments, each module in the Modular Expander Subsystem 103, 216 comprises a modular expander 211, with input and outlet valves or ports (not shown), to produce mechanical work from the expanding vapour.

In one or more embodiments, each module of the expander 211 includes the essential components of a generator within it as illustrated in FIG. 4, allowing it to also function as a modular generating system. In some embodiments, the generator includes cylinder walls containing electrical coils 406 and pistons including permanent magnets 404, with intake and outlet valves or ports 422. Reciprocating movement of the magnets 404 relative to the coils 406 generates electrical output power.

Optionally, pistons and associated pistons of the modules of the expander 211 are configured in pairs, such that, for a given pair, movement of the pistons are mutually synchronized and are in mutually opposite directions, to reduce vibration within the system 100 and associated acoustic noise of operation. Optionally, a triad combination or higher order of pistons and associated cylinders are arranged in a radial configuration and synchronized in their operation such that vibration in the Modular Expander Subsystem 103, 216 is reduced. Optionally, two or more pistons and associated cylinders are operated out of phase with each other, in order to improve power quality.

In the Modular Expander Subsystem 103, of which an embodiment is illustrated in FIG. 3, the vaporized working fluid produced by the Evaporator Subsystem 102 is admitted through a port or a valve 302 controlled by the Modular Expander Control System 221 into a Modular Expander 302. In some embodiments, the inlet and outlet valves are electrically controlled and are designed to be fast acting and to permit high flows. In some embodiments, the valves may be solenoid valves. In other embodiments, the ports or valves may be of other designs without any limitations.

In some embodiments, this Modular Expander Subsystem 103 may include a single- or double-acting piston-cylinder assembly, with or without a bounce chamber (not shown). In other embodiments, it may include a turbine or a screw expander, or other device (not shown); for example, a multi-stage turbine may be employed.

As the vaporized working fluid expands in the Modular Expander 302, it performs work on the Modular Generator 303. When the Expander 302 is a piston-cylinder assembly 306, the work may consist of exerting force on the piston, which is transmitted by a shaft 304 to a modular generator. In other embodiments (not shown), the work may consist of torque transmitted to a shaft.

When the gas has expanded to the desired expansion ratio, the opening of a port or valve 301 controlled by the Modular Expansion Control Subsystem 221 allows the expanded gas to enter the Condenser Subsystem 216.

### Condenser Subsystem 105

Referring again to FIG. 2, the Condenser Subsystem 105 comprises:
a coolant 213 that is used to cool the working fluid 208 in the condenser 212; optionally, a coolant 213 includes glycolated water;
a coolant pump 214 to circulate said coolant 213;
a cold source 224, consisting of or comprising ambient air, a natural body of water, an aquifer, or any other cold source;
a cooler 215, consisting in some embodiments of a dry cooler, a cooling tower or a geothermal cooling system, or any other such device or system, to transfer heat from the coolant to the cold source before returning the coolant to the condenser;
a condenser 212 to cool the expanded working fluid vapour until it enters the liquid phase;
a working fluid pump 209 to pressurize the condensed working fluid and return it to the phase-change heat exchanger 204.

In some embodiments, the condenser 212 uses circulating air to withdraw heat from the working fluid 208 (not shown). In other embodiments, it uses circulating water, or another fluid, to withdraw heat from the working fluid 208, with or with evaporation (not shown). In some embodiments, where the installations are located in areas of cold climate, the cold temperatures of outdoor air are used directly or indirectly to cool the working fluid 208. In other embodiments, geothermal loops are used to provide ground-source cooling. In other embodiments, natural bodies of water, aquifers or any other cold source may be used to further lower the temperature of the coolant 213.

In some embodiments, the coolant is further cooled by refrigeration or any other technology, in order to increase the temperature differential between the hot and cold sides of the modular expander.

In some embodiments, the temperature and pressure of the condenser 212 are varied from one season to another, in order to take advantage of the colder condensing temperatures available in winter.

In some embodiments using ground-source cooling, cold ambient air is circulated underground during the winter in order to further cool the ground in order to reduce the ground-source temperature during the next summer.

In some embodiments, the formulation of at least one of the working fluid 208 and the coolant 213 is varied from one season to another, in order to take advantage of the colder condensing temperatures available in winter.

### Modular Generation Subsystem 104

The Modular Generation Subsystem 104, 217 comprises one or more modular generation devices. In one or more embodiments, each module of the Modular Generation Subsystem comprises:
as illustrated in FIG. 3, a linear generator 303 that is coupled to a shaft 304 of a piston-cylinder assembly 302, to convert the mechanical work to electrical power;
a variable frequency drive (VFD) 504; and
an electrical emergency brake 501.

In other embodiments, each module of the Modular Generation Subsystem 104 comprises a mechanism to convert linear to rotary motion, and a rotary generator (not shown).

In one or more embodiments, each module of the Modular Generation Subsystem 104 is built into the modular expander, such that a single apparatus carries out the two functions (expander and generator) as illustrated in FIG. 4.

Each module of the Modular Generation Subsystem 104, 217 uses the mechanical work produced by one module of the Modular Expander Subsystem 103, 216 to produce electrical power. In some embodiments, where the work takes the form of force exerted upon a piston, the Modular Generation Subsystem 104, 217 may include a linear generator 303 coupled with a variable frequency drive (VFD) 504. In some embodiments, the linear force of the piston is converted by mechanical or hydraulic means to rotary force, and is then coupled with a rotary generator (not shown) to generate electricity.

In some embodiments, the linear generator is in the form of a tubular linear permanent magnet synchronous machine. In other embodiments, it may be in a different form.

In some embodiments, the Modular Generation Subsystem 104 and the Modular Expander Subsystem 103 are integrated into a single device, see FIG. 4. In some embodiments, the aforesaid permanent magnets 404 are integrated into the piston 412 and the electrical coils 406 are integrated into the cylinder walls 418 of a single- or double-acting piston-cylinder assembly, with or without a bounce chamber (not shown), such that current is generated in the coils as the piston moves as a result of pressurized vapour being admitted into the cylinder.

The physical parameters of the linear generator may be chosen so as to optimize overall power production and efficiency. These parameters may include, but not limited to, permanent magnet (PM) radial and axial thickness; PM pole pitch and gap; slot pitch, width, opening width and height; tooth width and shoe height; stator core and Shaft/PM outer diameters; and airgap length and diameter.

In some embodiments, the VFD 504 presents an electrical load to the modular generator 506, at a level fixed by the Modular Generation Control Subsystem 106, 507 and which may vary in real time based on system conditions. In some embodiments, the VFD 504 converts the AC output of the generator to DC and then back to AC, at a frequency and voltage set by the Modular Generation Control Subsystem 106, 507.

In one or more embodiments, the VFD 504 also includes a grid-tie interface 505, which allows the power produced by the system to be delivered to the local power grid (for example, 50 Hz or 60 Hz public power grid), respecting all regulatory norms in effect.

In some embodiments, an electrical emergency brake 501 functions to stop the piston very rapidly in the event of an electrical or mechanical fault.

In some embodiments, said electrical emergency brake 501 consists of or comprises a bank of resistors 502 and a set of relays 503 to selectively couple the resistors 502 to the modular generator 506 in an emergency situation. Thus, the relays 503 are configured such that, under a fault condition, the modular generator 506 is connected to the resistor bank 502 rather than to the VFD 504, causing the generator shaft to decelerate and stop rapidly.

In some embodiments, the Modular Generation Subsystem 104 also includes a hypercapacitor, supercapacitor or another high-speed electric storage device (not shown, e.g. a solid-electrolyte battery), which is designed to ensure that the power output remains constant over time, despite the variations that may be caused by changes in the piston trajectory and, in embodiments including a linear generator, at the moments when it changes direction.

### Control Subsystem 106

In embodiments of the present disclosure, the Control Subsystem 106, 218 has six primary subsystems, as illustrated in FIGS. 1 and 2. They are:
(i) the Heat Transfer Medium Control System (HTMCS) 107, 219 that ensures that the pump or pumps 205 that circulate the liquid heat transfer medium 202 between the electronic components equipment 203 and the Evaporator Subsystem 102 are controlled in order to maintain the temperature of the heat transfer medium 202 at the appropriate temperature, such as to ensure optimal operating conditions for the computing equipment 203 and to maximize the efficiency of the conversion of waste heat to electrical power;
(ii) a Module Control system (MCS) (not shown), which controls valves connecting the Evaporator Subsystem 102 to the various Modular Expander Subsystems 103. The MCS determines which expander and generator modules are operating at any given moment, depending on the heat available, which in turn depends on the level of activity of the data centre. In order to maximize the efficiency of the power conversions, most of the generator modules in operation may operate at or near their point of maximum efficiency, while one or more modules may operate at a level farther from its point of maximum efficiency;
(iii) an Evaporator Control System (ECS) 108, 220, that controls the operation of the working fluid pump 205, that circulates the working fluid 208 between the evaporator 204, the condenser 212 and the modular expander(s) 211;
(iv) a Modular Expander Control System (MECS) 109, 221, which controls the timing of the opening and the closing of valves 301 of the Modular Expander Subsystem 103, 216, including the inlet valves (not shown) which admit pressurized gas into each modular expander, and the outlet valves (not shown) which admit spent gas from each modular expander 211 into the condenser 212. These valve timings are chosen to optimize power production and efficiency. In some embodiments, this is effected by maximizing effective stroke length, maximizing expansion ratio, minimizing turnaround time, and minimizing power drop-off at end of stroke. In some embodiments, where the Modular Expander Subsystem 103, 216 consists of or includes more than one expander, the Modular Expander Control System 109, 221 may ensure that the various modular expanders operate out of phase with each other;
(v) a Modular Generation Control System (MGCS) 110, 217, which controls the generator and, in some embodiments, the Variable Frequency Drive 504. In some embodiments, the MGCS 110, 217 manages the load presented to the generator in real time, in order to maintain constant power output despite the decreasing velocity and force of the piston (or, in some embodiments, the decreasing velocity and torque of the shaft) of the expander. More specifically, the MGCS 110, 217 decreases the load such that the expander velocity increases as the force (or torque) decreases. As a result, voltage increases as current decreases, and power output remains constant. In some embodiments, the MGCS 110, 217 also controls the grid-tie interface 505. In some embodiments, the MGCS 110, 217 also controls the hypercapacitor, supercapacitor or high-speed electrical storage device that ensures power quality (not shown); and
(vi) a Condenser Control Subsystem (CCS) 111, 223, which controls the flow rate of the coolant pump 214, to ensure that the condenser temperature and pressure remain at their optimal levels.

In some embodiments, the Control Subsystem 106 controls other aspects of the system 100 operation as well.

The present disclosure also relates to a method for waste-heat recovery and power generation as described above. The various embodiments and variants disclosed above apply mutatis mutandis to the present method without any limitations. Steps 800 to 830 of the method are illustrated in FIG. 8. The method is used for recovering and utilising waste heat from a computing centre, data centre or other assemblage of computing equipment including electronic components 203. In the first step 800, the method comprises collecting the heat from the electronic components 203 in a heat transfer fluid. In the second step 810, the method comprises transferring heat from the heat transfer fluid to a pressurized phase-change working fluid in a phase-change heat exchanger. In the third step 820, the method comprises directing vaporized working fluid(s) released from the phase-change heat exchanger to an expander, where they produce mechanical power. In the fourth step 830, the method comprises using the mechanical power produced in the expander to power a generator, producing electricity.

Optionally, the method includes configuring the expander to consist of or comprise one or more single- or double-acting piston-cylinder assemblies.

Optionally, the method includes configuring the single- or double-acting piston-cylinder assemblies to drive a linear electric generator coupled with a variable-frequency drive (VFD).

The invention implemented as the system 100 may now be described with reference to specific example implementations. It may be understood that the following example implementations are intended to describe embodiments of the invention and are not intended to limit the invention in any way.

### Fluids for the System 100

An example of the liquid heat transfer medium 202 is described in the foregoing. However, it will be appreciated that other types of liquid heat transfer medium 202 can alternatively or additionally be used when implementing the System 100. For example, alternative types of fluids for implementing the liquid heat transfer medium 202 include one or more of:
(i) water (for example, for direct-to-chip applications);
(ii) an immersion fluid in a Novec (note: “Novec” is a trademark) range of proprietary products developed by 3M Corporation, as described at https://www.3mcanada.ca/3M/en_CA/novec-ca/immersion-cooling-for-data-centres/; for example Novec 7000 which is 1-methoxyheptafluoropropane (C3 F 7 OCH 3) and/or Novec 7300 which is a mixture of Methyl nonafluorobutyl ether and Methyl nonafluoroisobutyl ether;
(iii) one or more types of oils, for example including mineral oil;
(iv) a halogenated hydrocarbon or halogenated carbon compound, for example Carbon Tetrachloride;
(v) an immersion fluid produced from methane;
but not limited thereto.

When selecting a suitable working fluid 208, one or more of the following substances may be used in the System 100:

| | |
|---|---|
| (i) | Propylene, |
| (ii) | Propane, |
| (iii) | R1234yf, |
| (iv) | R227ea, |
| (v) | R134a, |
| (vi) | R1234ze, |
| (vii) | RC318, |
| (viii) | R152a, |
| (ix) | R600a, |
| (x) | R236fa, |
| (xi) | R245fa, |
| (xii) | R245ca, |
| (xiii) | MM, |
| (xiv) | Cyclohexane, |
| (xv) | Benzene, |
| (xvi) | Toluene, |
| (xvii) | MDM, |

But not limited thereto.

For the coolant 213, it is most convenient to use an aquatic fluid, for example water in combination with one or more additives that lower a freezing point of the water. Examples of the one or more additives include:
(i) ethylene glycol; and
(ii) propylene glycol.

### Practical Implementation

In one example, a company operates a data centre providing cloud computing services, which consumes up to 1000 kW of power. The computing equipment (203) is cooled by single-phase immersion cooling, where the assemblages of computing equipment are immersed in a bath of dielectric fluid.

A pump circulates said dielectric fluid from the immersion baths to a heat exchange evaporator. The pump flow rate is controlled such that the temperature in the bath remains constant, at 65° C., despite fluctuations in the power consumption of the computing equipment.

The heat exchange evaporator transfers heat from said dielectric fluid to a working fluid (208), consisting of a hydrofluoroolefin refrigerant. The working fluid pump adjusts the flow of working fluid such that, in said heat exchange evaporator, the refrigerant is heated to 58° C. at a pressure of 12 Bar, and the dielectric fluid is cooled to 25° C.

The pressurized vapour generated by the evaporator is directing by piping to, in this example, three (3) or four (4) modular expanders, depending on the amount of waste heat being generated at any given time. In some embodiments, each modular expander consists of a double-acting piston-cylinder assembly, the shaft of which is connected to a module of the modular generation subsystem. In other embodiments, the expander also fulfills the function of the modular generation subsystem, due to the inclusion of permanent magnets in the piston and the inclusion of coils in the cylinder walls.

Ports or valves controlled by the modular expander control system allow vapour to enter the modular expanders. These valves are closed after a certain lapse of time, allowing the vapour to expand in the cylinder, applying force to the piston which in turn, in some embodiments, displaces the shaft of the modular generation subsystem. When the desired expansion ratio has been achieved, a second valve controlled by the modular expander control system opens, allowing the expanded gas to vent to the condenser. In the condenser, water, air or another medium is used to cool the expanded vapour to the point where it condenses to a liquid phase, whereupon the working fluid pump returns it to the pressurized vessel.

In some embodiments, the modular generation subsystem is a synchronous linear generator, consisting of a tubular slider containing axially magnetized permanent magnets alternated with disk spacers, and of a stator comprised of series-connected three-phase windings.

The amperage, voltage and frequency of the electric current generated by the modular generation subsystem vary depending on the force and velocity of the piston, and on the electrical load presented to the modular generation subsystem. The force of the piston depends on pressure of the vapour behind it, which varies during the vapour expansion phase. The piston accelerates when that force is greater than the effective force resulting from the generator load, which is controlled by the modular generation control system.

The electric current produced by the modular generation subsystem is carried by wires to the Variable Frequency Drive (VFD), which converts it first to direct current and then back to alternating current, synchronized with the electric grid. The VFD creates a resistive force or load, opposing that of the pressurized vapour. In some embodiments, the load presented by the VFD to the generator is managed in real time by the generation control system such that the power output from the Modular Generator is maintained at a constant or near-constant level.

In some embodiments, a hypercondenser, supercapacitor, solid-electrolyte battery or other electricity storage system is connected to the generator allows the power output to be equalized over time.

In this example, the four (4) modular units produce almost 25 kW each, when the data centre is operating at full capacity. The 100 kW produced allow the data centre to reduce its purchases from the local utility by that same amount, reducing the data centre's costs and environmental footprint. When the data centre's power consumption falls below 750 kW, the MCS removes one or more modular generating units from operation, so that three (3) or fewer modular generating units are in service.

Further example implementations of the System 100 are as follows:

Example 1: A system to recover and utilise waste heat from a computing centre, data centre or other assemblage of computing equipment (including electronic components), in which:
heat from the operation of the electronic components is absorbed by a liquid;
heat from said liquid is transferred, directly or indirectly, to a working fluid in a pressure-resistant vessel, vaporizing said working fluid;
valves operated by a control system allow vaporized working fluid to pass from the pressure-resistant vessel to an expander;
vaporized working fluid released from the pressure-resistance vessel is allowed to expand in an expander, producing mechanical power (e.g. to drive an electric generator);
a condenser is used to condense the partially cooled vapour expelled from the expander;
a pump returns the condensed working fluid to the pressure-resistant vessel; and
a control system controls the operations of said valves and pumps.

Example 2: The system of Example 1, in which the liquid is a dielectric fluid in which the electronic components are immersed.

Example 3: The system of Example 2, in which the dielectric fluid is a phase-change fluid which is cooled by coils placed above the immersed electronic components, through which a heat-transfer fluid circulates.

Example 4: The system of Example 3, in which the heat-transfer fluid is a phase-change fluid which, in its vaporized state, acts as the working fluid which is allowed to expand in the expander.

Example 5: The system of Example 2, in which the dielectric fluid circulates through a heat-exchange evaporator, evaporating the working fluid.

Example 6: The system of Examples 1, 2, 3, 4 and 5, in which the working fluid is selected such that its thermodynamic properties result in optimal heat recovery from the system.

Example 7: The system of Examples 1, 2, 3, 4, 5 and 6, in which the working fluid designed to result in optimal heat recovery from the system is a zeotropic fluid.

Example 8: The system of Examples 1, 2, 3, 4, 5, 6 and 7, in which the expander consists of one or more single- or double-acting piston-cylinder assemblies which are used to drive an electric generator.

Example 9: The system of Example 8, in which the electric generator is coupled with a variable-frequency drive (VFD).

Example 10: The system of Example 9, in which the VFD is controlled in order to regularize the power output of the generator.

Example 11: The system of Example 10, in which the temperature and pressure of the condenser vary from one season to another, in order to take advantage of the colder condensing temperatures available in winter.

Example 12: The system of Example 11, in which the electric generator is a linear electric generator.

Example 13: The system of Example 12, in which the load provided by the VFD is controlled in real time in order to manage the piston trajectory and to maintain the generator's power output at a near-constant level.

Example 14: The system of Example 13, in which one or more piston-cylinder assemblies and individual assemblies can be added to or removed from operation as the vapour flow varies, such that each assembly operates at or close to its optimal operating regime.

Example 15: The system of Example 13, in which the various assemblies are operated out of phase to each other, in order to improve power quality.

Example 16: The system of Example 1, 2, 3, 4, 5, 6, 7, 8, 9, 10, 11, 12 and 13, in which each module of the modular generation subsystem is built into the modular expander, such that a single apparatus carries out the two functions (expander and generator).

Example 17: The system of Example 16, in which permanent magnets are integrated into the piston head and the coils are integrated into the cylinder walls of a single- or double-acting piston-cylinder assembly, such that current is generated in the coils as the piston moves as a result of pressurized vapour being admitted into the cylinder.

Examples of methods of operating the System 100 are provided in the following: Example 18: A method for recovering and utilising waste heat from a computing centre, data centre or other assemblage of computing equipment, the method comprising:
using the mechanical power produced in the expander to power a generator, producing electricity.

Example 19: The method of Example 18, in which the expander consists of one or more single- or double-acting piston-cylinder assemblies.

Example 20: The method of Example 18, in which the single- or double-acting piston-cylinder assemblies drive a linear electric generator coupled with a variable-frequency drive (VFD).

1. A system for converting waste hea into electricity, the system comprising:
a heat capture subsystem configured to hold a liquid heat transfer medium therein, wherein the heat capture subsystem, in use, enables the liquid heat transfer medium to absorb the waste heat;
an evaporator subsystem, comprising a phase-change working fluid, wherein the working fluid is configured to change from a liquid state to a gaseous state by absorbing the waste heat absorbed into the liquid heat transfer medium;
a modular expander subsystem comprising at least one modular expansion device, wherein the expander subsystem is coupled to the evaporator subsystem via at least one fluid flow control element, wherein pressurized working fluid in the gaseous state is directed towards the expander subsystem using the at least one fluid flow control element, and wherein the pressurized gaseous working fluid expands, producing mechanical work;
a modular generation subsystem coupled to the expander subsystem, wherein a modular generator, when in operation, is configured to produce electrical energy from the mechanical work created by the expansion of the pressurized gaseous working fluid in the modular expansion device;
a condenser subsystem connected to the expander subsystem, wherein a condenser, in operation, liquifies expanded working fluid from a gaseous state or a mixed state to the liquid state, and then returns working fluid in the liquid state to the evaporator subsystem;
a control subsystem that controls operations of at least one of the other subsystems; and
a variable frequency drive (VFD) electrically coupled to the generator, wherein the VFD, in operation, provides an electrical load to the generator.

2. The system of claim 1, wherein the condenser subsystem comprise a cold source, a cooler, a coolant liquid, a condenser and a coolant pump that circulates the coolant liquid between the cooler and the condenser, and wherein the evaporator subsystem comprises a phrase-change working fluid that is selected based upon the temperature of the liquid heat transfer medium and the temperature of the cold source that cools the condenser, a working fluid pump that circulates said working fluid and increases its pressure, and a phase-change heat exchange evaporator that transfers heat from said liquid heat transfer medium to said working fluid, causing said working fluid to change from a liquid state to a gaseous state.

3. (canceled)

4. (canceled)

5. (canceled)

6. The system according to claim 2, wherein the temperature of the cold source is further decreased by ground-source cooling, by water circulated from a natural water body or aquifer, by refrigeration, or by any other means.

7. (canceled)

8. The system according to claim 1, wherein a modular generation control system controls the electrical load provided by the VFD to control the velocity of the modular generator in order to regulate the electric power produced by said modular generator.

9. (canceled)

10. (canceled)

11. The system according to claim 1, wherein the modular generator is a linear generator.

12. The system according to claim 1, wherein the heat capture subsystem is implemented as a bath filled with the liquid heat transfer medium, wherein the liquid heat transfer medium is a phase-change dielectric fluid, and wherein a source of waste heat includes at least one assemblage of computing equipment is-immersed in the phase-change dielectric fluid.

13. The system according to claim 12, wherein the phase-change liquid heat transfer medium is cooled by a phase-change working fluid circulating in coils that are placed above the bath.

14. The system according to claim 12, wherein the phase-change dielectric fluid acts as the working fluid which, in its gaseous state, is introduced into the expander subsystem.

15. (canceled)

16. The system according to claim 1, wherein the temperature of the heated phase-change working fluid is further increase by a solar thermal heating device or by any other means.

17. The system according to claim 16, wherein cold ambient air is circulated underground during the winter in order to further cool the ground in order to reduce the ground-source temperature during the following summer.

18. (canceled)

19. The system according to claim 1, wherein the phase-change working fluid consists of or comprises a substance that is in a gaseous state at ambient temperatures and at atmospheric pressure, and wherein the condenser is maintained at a pressure higher than atmospheric pressure such that the working fluid emerges from said condenser in liquid form.

20. The system according to claim 1, wherein a formulation of the phase-change working fluid is varied on a seasonal basis, to optimize the thermodynamic efficiency of the system, taking into account seasonal variations in the ambient temperature.

21. The system according to claim 1, wherein a plurality of modular expanders and a plurality of modular generators are implemented, and in which the number of modular expanders and modular generators in operation is selected based on the amount of the waste heat that is available, and wherein the plurality of modular expanders operate out of phase with respect to each other.

22. (canceled)

23. The system according to claim 1, wherein the expander subsystem and the generator are integrated into an expander-generator assembly that performs functions of the expander subsystem and the generator.

24. An integrated expander-generator assembly comprising:
a plurality of permanent magnets;
a plurality of coils;
a piston; and
a cylinder,
arranged such that the plurality of permanent magnets are arranged inside the piston and the plurality of coils are arranged along a length of the cylinder,
and wherein, when in use, pressurized gas expanding in the integrated expander-generator assembly produces a mechanical force that actuates the piston in the cylinder, and wherein upon such actuation, a relative motion between the plurality of permanent magnets and the plurality of coils produces electricity.

25. (canceled)

26. An integrated expander-generator assembly according to claim 24, wherein the integrated expander-generator assembly is usable in a system for converting waste heat into electricity.

27. (canceled)

28. (canceled)

29. A method for converting waste heat into electricity, the method comprising:
arranging a heat capture subsystem to hold a heat transfer fluid therein, wherein the heat capture subsystem, in use, enables the heat transfer fluid to absorb the waste heat;
arranging an evaporation subsystem comprising a phase change heat exchanger to be coupled to the heat capture subsystem, and filling the phase change heat exchanger with a working fluid, wherein the working fluid is vaporized from a liquid phase to a gaseous phase when the working fluid absorbs the waste heat from the heat transfer fluid, the working fluid being selected based upon the temperature of the waste heat;
arranging an expander subsystem to be coupled to the evaporator subsystem via at least one fluid flow control element, wherein pressurized vapour of the working fluid that emanates from the evaporator subsystem is directed towards the expander subsystem using the at least one fluid flow control element, and wherein when the expander subsystem is in use, the pressurized working fluid vapour is allowed to expand in the expander subsystem, producing a mechanical force for actuating the expander;
arranging a generator subsystem to be coupled to the expander subsystem, wherein the generator, when in operation, produces electricity using the mechanical force created by the expansion of the pressurized working fluid vapour;
arranging a condenser subsystem to be connected to the expander subsystem, wherein the condenser, when in operation, liquifies the expanded working fluid vapour from the gaseous phase to the liquid phase, and wherein the condensed working fluid is returned under pressure to the evaporator subsystem;
configuring a control subsystem for controlling operations of the other subsystems and
arranging a variable frequency drive (VFD) to be electrically coupled to the generator, wherein the VFD is operable for providing an electrical load to the generator to produce a resistive force opposing the mechanical force produced by the pressurized vapour of the working fluid.

30. (canceled)

31. The method according to claim 29, further comprising configuring a controller for controlling the electrical load provided by the VFD for to regulate the power output of the generator.

32. (canceled)

33. The system according to claim 1, wherein a source of waste heat includes at least one assemblage of computing equipment immersed in the liquid heat transfer medium.

34. The system according to claim 1, wherein a source of waste heat includes at least one assemblage of computing equipment and wherein the heat capture subsystem includes an assemblage of pipes and manifolds circulating the liquid heat transfer medium, said heat transfer medium cooling electronic components of the computing equipment by passing through one or more heat exchangers in thermal exchange contact with the electronic components.
